(19) United States
(12) Patent Application Publication
(10) Pub. No.: US 2024/0314985 A1
(43) Pub. Date: Sep. 19, 2024

(54) POWER CONVERSION APPARATUS

(71) Applicant: FUJI ELECTRIC CO., LTD., Kawasaki-shi (JP)

(72) Inventor: Takanori SHINTANI, Suzuka-shi (JP)

(21) Appl. No.: 18/418,841

(22) Filed: Jan. 22, 2024

(30) Foreign Application Priority Data
Mar. 13, 2023 (JP) 2023-038930

(51) Int. Cl. H05K 7/20; H02M 1/32; H02M 3/00; H02M 3/156; H02M 7/00; H02M 7/5387

(52) U.S. Cl. CPC H05K 7/20927; H02M 1/327; H02M 3/003; H02M 3/156; H02M 7/003; H02M 7/53871

(57) ABSTRACT

A power conversion apparatus includes a converter, an inverter, and a cooler. A cooling flow path is arranged inside the cooler. A converter-side flow path is connected to an inverter-side flow path so that cooling liquid passes through the entire inverter-side flow path and then passes through the converter-side flow path in the cooling flow path.

### CROSS-REFERENCE TO RELATED APPLICATION

The present application claims priorities of Japanese Patent Applications No. JP2023-038930 filed on Mar. 13, 2023, and No. JP2023-141265 filed on Aug. 31, 2023, disclosures of which are hereby incorporated by reference.

### BACKGROUND OF THE INVENTION

### Field of the Invention

The present invention relates to a power conversion apparatus, and particularly to a power conversion apparatus including a cooling flow path.

### Description of the Background Art

Power conversion apparatus including a cooling flow path is known in the art. Such a power conversion apparatus is disclosed in Japanese Patent Laid-Open Publication No. JP 2009-027901, for example.

Japanese Patent Laid-Open Publication No. JP 2009-027901 discloses a power conversion apparatus including an inverter, a DC/DC converter, and a cooling flow path through which refrigerant flows to cool the inverter and the DC/DC converter.

In this power conversion apparatus, the cooling path is interposed between the inverter and the DC/DC converter so that the refrigerant flowing through the cooling path cools the inverter and the DC/DC converter.

### SUMMARY OF THE INVENTION

In Japanese Patent Laid-Open Publication No. JP 2009-027901, the cooling path is interposed between the inverter and the DC/DC converter (direct current/direct current converter) so that the refrigerant flowing through the cooling path cools the inverter and the DC/DC converter. Accordingly, a part of the refrigerant flowing through the cooling path on an inverter side cools the inverter, and one other part of the refrigerant flowing on a DC/DC converter side cools the DC/DC converter. For this reason, the inverter and the DC/DC converter cannot be efficiently cooled.

The present invention is intended to solve the above problem, and one object of the present invention is to provide a power conversion apparatus capable of efficiently cooling an inverter and a converter.

In order to attain the aforementioned object, a power conversion apparatus according to one aspect of the present invention includes a converter configured to transform direct current power input from a direct current power source; an inverter configured to convert the direct current power transformed by the converter into alternate current power and to supply the converted alternate current power to a load; and a cooler arranged between the inverter and the converter, wherein a cooling flow path is arranged inside the cooler, and includes an inverter-side flow path and a converter-side flow path connected to the inverter-side flow path; a plurality of protrusions is formed in a part of the inverter-side flow path; and the converter-side flow path is connected to the inverter-side flow path so that cooling liquid passes through the entire inverter-side flow path and then passes through the converter-side flow path in the cooling flow path.

In the power conversion apparatus according to the aforementioned aspect of this invention, as discussed above, the cooler arranged between the inverter and the converter has a cooling flow path including an inverter-side flow path, and a converter-side flow path connected to the inverter-side flow path. Accordingly, the inverter and the converter can be individually cooled by flowing the cooling liquid through the inverter-side flow path and then the converter-side flow path. According to this configuration, because temperature difference in the cooling liquid flowing through the same flow path can be reduced, it is possible to prevent unintended convection of the cooling liquid caused by temperature difference. Consequently, the inverter and the converter can be efficiently cooled by the cooling liquid flowing through the cooling flow path. Also, because the converter-side flow path is connected to the inverter-side flow path so that cooling liquid passes through the entire inverter-side flow path and then passes through the converter-side flow path in the cooling flow path, the inverter can be efficiently cooled as compared with a case in which cooling liquid passes through the converter-side flow path and then passes through the inverter-side flow path.

In the power conversion apparatus according to the aforementioned aspect, it is preferable that the cooling flow path further includes a first connection flow path arranged in one end part in a longitudinal direction in which the cooler extends, to connect the converter-side flow path to the inverter-side flow path in the cooler. According to this configuration, because the converter-side flow path is connected to the inverter-side flow path in the cooler by the first connection flow path, the cooling flow path can be formed to flow the cooling liquid through the inverter-side flow path, the first connection flow path and then through the converter-side flow path. Consequently, a configuration of the cooler can be simplified dissimilar to a case in which the converter-side flow path is connected to the inverter-side flow path by a flow path outside the cooler. Also, in a case in which the first connection flow path is a single flow path, because the converter-side flow path is connected to the inverter-side flow path by the first connection flow path, the configuration of the cooler can be further simplified as compared with a case in which the converter-side flow path is connected to the inverter-side flow path by two or more flow paths.

In this configuration, it is preferable that the cooler has a flow inlet through which the cooling liquid flows into the cooler, and a flow outlet through which the cooling liquid flows out of the cooler; and that the flow inlet, the inverter-side flow path, the first connection flow path, the converter-side flow path, the flow outlet are connected in this order, and the cooling flow path turns in the first connection flow path, which is arranged in the one end part in the longitudinal direction. According to this configuration, it is possible to prevent size increase of the cooler in the longitudinal direction as compared with a case in which the flow inlet, the inverter-side flow path, the first connection flow path, the converter-side flow path, and the flow outlet are connected linearly in the longitudinal direction. Also, the configuration of the cooler can further be simplified as compared with a case in which the inverter-side flow path and the converter-side flow path are alternately connected to each other.

In the configuration in which the cooler includes the flow inlet and the flow outlet, it is preferable that the cooling flow path is formed so that the inverter-side flow path and the converter-side flow path overlap each other as viewed in a facing direction in which the inverter and the cooler face each other. According to this configuration, it is possible to prevent size increase of the cooler in a direction orthogonal to the facing direction as compared with a case in which the cooling flow path is not formed so that the inverter-side flow path and the converter-side flow path overlap each other as viewed in the facing direction.

In the configuration in which the cooler includes the flow inlet and the flow outlet, it is preferable that the inverter-side flow path is formed linearly in the longitudinal direction as viewed in a facing direction in which the inverter and the cooler face each other; and that the converter-side flow path is formed so that flow (s) of the cooling liquid meanders/meander as viewed in the facing direction. According to this configuration, because the inverter-side flow path is formed linearly in the longitudinal direction, the inverter-side flow path can be prevented from becoming complicated so that the configuration of the cooler can be simplified. Also, because the converter-side flow path is formed so that flow(s) of the cooling liquid meanders/meander, the converter can be more efficiently cooled by meandering the flow (s) of the cooling liquid in the converter-side flow path depending on an arrangement area of the converter.

In this configuration, it is preferable that the cooling flow path is formed so that the cooling liquid branches into a plurality of flow paths in the converter-side flow path. According to this configuration, it is possible to separately flow the cooling liquid through the converter-side flow path in a wide area. As a result, the cooling liquid can be distributed evenly in the converter-side flow path so that the converter can be more efficiently cooled.

In the configuration in which the cooler includes the flow inlet and the flow outlet, it is preferable that the flow inlet and the flow outlet are arranged in another end part of the cooler in the longitudinal direction. According to this configuration, because both pipes that are connected to the power conversion apparatus to flow the cooling fluid into and out of power conversion apparatus are connected to another end part of the cooler, it is possible to prevent size increase of the power conversion apparatus including the pipes in the longitudinal direction of the cooler as compared with a case in which the pipes are connected to one end part and another end part of the cooler in the longitudinal direction.

In the configuration in which the inverter-side flow path is formed linearly in the longitudinal direction as viewed in the facing direction, it is preferable that the cooler includes a main body including the inverter-side flow path and the converter-side flow path formed in the main body, and a flat-plate-shaped inverter lid to which the inverter is attached, and which forms the inverter-side flow path formed linearly as viewed in the facing direction together with the main body. According to this configuration, because an inverter lid to which the inverter is attached can be brought in direct contact with the cooling liquid flowing through the inverter-side flow path, it is possible to efficiently dissipate heat generated by the inverter through the inverter lid.

In this configuration, it is preferable that the plurality of protrusions is arranged in the inverter-side flow path, and protrudes toward an interior of the inverter-side flow path. According to this configuration, a flow speed of the cooling liquid flowing in the inverter-side flow path can be increased by adjusting the flow of the cooling liquid by using the plurality of protrusions protruding toward the interior of the inverter-side flow path. As a result, it is possible to efficiently cool the inverter. Also, because a heat dissipation area (heat transfer area) in the inverter-side flow path can be increased by the plurality of protrusions, it is possible to more efficiently cool the inverter.

In the configuration in which the cooler includes the flow inlet and the flow outlet, it is preferable that the inverter includes a first switching element module and a second switching element module configured to convert the direct current power into the alternate current power; and that the inverter-side flow path includes a first inverter flow path formed corresponding to the first switching element module and a second inverter flow path formed corresponding to the second switching element module, and the first inverter flow path and the second inverter flow path are arranged linearly in the longitudinal direction and connected to each other. According to this configuration, the first switching element module and the second switching element module can be cooled by the cooling liquid flowing through the first inverter flow path and the cooling liquid flowing the second inverter flow path, respectively. Consequently, it is possible to more efficiently cool the first switching element module and the second switching element module as compared with a case in which the first switching element module and the second switching element module are cooled by the cooling liquid flowing through the same flow path.

In the configuration in which the first inverter flow path and the second inverter flow path are connected to each other, it is preferable that the cooling flow path further includes a second connection flow path curved toward a side where the converter is arranged, and connecting the first inverter flow path and the second inverter flow path to each other. According to this configuration, the first and second inverter flow paths can be connected by the curved flow path, which is curved toward the side where the converter is arranged to be able to bypass a part between the first and second inverter flow paths. As a result, the first and second inverter flow paths can be more flexibly connected depending on arrangements and shapes of the first and second inverter flow paths as compared with a case in which the first inverter flow path and the second inverter flow path are connected by a linear flow path.

In the configuration in which the first inverter flow path and the second inverter flow path are connected to each other, it is preferable that the second inverter flow path is formed downstream of the first inverter flow path; and that the plurality of protrusions is arranged in the second inverter flow path.

In this configuration, it is preferable that the plurality of protrusions is arranged in the second inverter flow path, and protrudes toward an interior of the second inverter flow path to adjust a flow of the cooling liquid. According to this configuration, a flow speed of the cooling liquid flowing through the second inverter flow path can be increased by adjusting the flow of the cooling liquid flowing through the second inverter flow path by using the plurality of protrusions protruding toward the interior of the second inverter flow path. As a result, it is possible to efficiently cool the second switching element module. In addition, as compared with a case in which both the first and second inverter flow paths include such a plurality of protrusions, it is possible to prevent a structure of the inverter-side flow path in the cooler from becoming complicated and weight increase of the cooler caused by increase of the plurality of protrusions. Also, because a heat dissipation area (heat transfer area) in the second inverter flow path can be increased by the plurality of protrusions, it is possible to more efficiently cool the second switching element module.

In the configuration in which the first inverter flow path and the second inverter flow path are connected to each other, it is preferable that the second inverter flow path is formed downstream of the first inverter flow path; and that a flow depth of the second inverter flow path is shallower than a flow depth of the first inverter flow path. According to this configuration, because a cross-sectional area of the second inverter flow path can be smaller than a cross-sectional area of the first inverter flow path, a flow speed of the cooling liquid flowing through the second inverter flow path can be greater than a flow speed of the cooling liquid flowing through the first inverter flow path. As a result, the second switching element module can be more efficiently cooled by the second inverter flow path as compared with a case in which the first switching element module is cooled by the first inverter flow path. Consequently, it is possible to sufficiently cool the second switching element module even in a case in which the second switching element module generates a larger amount of heat than the first switching element module.

In the configuration in which the cooler includes the main body and the inverter lid, it is preferable that the cooler further includes a converter lid forming the converter-side flow path, which is formed so that flows of the cooling liquid meander as viewed in the facing direction, together with the main body; that the converter is attached to the converter lid; and that the converter lid includes a plurality of walls protruding toward an interior of the converter-side flow path and meandering the flows of the cooling liquid. According to this configuration, because flows of the cooling liquid that flow through the converter-side flow path are meandered by the plurality of walls, the converter can be more efficiently cooled by meandering the cooling liquid flowing through the converter-side flow path depending on an arrangement area of the converter.

In this configuration, it is preferable that the converter includes a direct current/direct current converter configured to transform a voltage of the direct current power into a different voltage, and a boost converter configured to boost the direct current power input from the direct current power source and to supply the boosted direct current power to the inverter; and that the converter-side flow path includes a first converter flow path formed corresponding to the boost converter, and a second converter flow path formed corresponding to the direct current/direct current converter. According to this configuration, since the boost converter and the direct current/direct current converter can be individually cooled by the cooling liquid through the first converter flow path and the second converter flow path, respectively, the boost converter and the direct current/direct current converter can be more efficiently cooled.

In the configuration in which the second connection flow path is provided, it is preferable that the cooler includes a main body including the inverter-side flow path and the converter-side flow path formed in the main body, and the cooler further includes a converter lid forming the converter-side flow path together with the main body; that the second connection flow path has an opening on the side where the converter is arranged; and that the converter lid includes a second-connection-flow-path former covering the opening. According to this configuration, the opening of the second connection flow path can be closed by the second-connection-flow-path former.

In this configuration, it is preferable that the second-connection-flow-path former has a convex shape protruding toward the side where the inverter is arranged. According to this configuration, because a depth of the second connection flow path is reduced, it is possible to reduce a pressure drop of refrigerant.

In the configuration in which the cooler includes the flow inlet and the flow outlet, it is preferable that the cooler includes a main body including the inverter-side flow path and the converter-side flow path formed in the main body, and a flat-plate-shaped inverter lid to which the inverter is attached, and which forms the inverter-side flow path together with the main body; and that the plurality of protrusions is arranged in the body part, and protrudes toward an interior of the inverter-side flow path. According to this configuration, because a flow speed of the cooling liquid can be increased by the plurality of protrusions, it is possible to more efficiently cool the inverter. Also, because a heat dissipation area (heat transfer area) in the inverter-side flow path can be increased by the plurality of protrusions, it is possible to more efficiently cool the inverter.

In this configuration, it is preferable that the inverter lid includes a fin. According to this configuration, because a heat dissipation area (heat transfer area) in the inverter-side flow path can be increased, it is possible to more efficiently cool the inverter.

In the configuration in which the cooler includes the main body and the inverter lid, it is preferable that the inverter includes a first switching element module and a second switching element module configured to convert the direct current power into the alternate current power; that the inverter-side flow path includes a first inverter flow path formed corresponding to the first switching element module and a second inverter flow path formed corresponding to the second switching element module; that the cooler includes a main body including the inverter-side flow path and the converter-side flow path formed in the main body, and flat-plate-shaped first and second inverter lids to which the first and second switching element modules are attached and which form the first and second inverter flow paths, respectively; and that the plurality of protrusions is arranged in at least one of the first and the second inverter flow paths. According to this configuration, because a flow speed of the cooling liquid can be increased by the plurality of protrusions, it is possible to more efficiently cool the inverter. Also, because a heat dissipation area (heat transfer area) in the inverter-side flow path can be increased by the plurality of protrusions, it is possible to more efficiently cool the inverter.

The foregoing and other objects, features, aspects and advantages of the present invention will become more apparent from the following detailed description of the present invention when taken in junction with the accompanying drawings.

### BRIEF DESCRIPTION OF THE DRAWINGS

FIG. 1 is a diagram showing a circuit configuration of a power conversion apparatus according to one embodiment of the present invention.

FIG. 2 is a schematic diagram showing the entire power conversion apparatus according to the embodiment.

FIG. 3 is a schematic diagram showing a flow of cooling liquid outside the power conversion apparatus according to the embodiment.

FIG. 4 is an exploded perspective view showing a base and lids of the power conversion apparatus according to the embodiment.

FIG. 5 is a plan view showing the base of the power conversion apparatus according to the embodiment as viewed from a Z2-direction side.

FIG. 6 is a plan view showing the base of the power conversion apparatus according to the embodiment as viewed from a Z1-direction side.

FIG. 7 is a cross-sectional view showing the base, an inverter, and a converter taken along an X direction (a longitudinal direction of the base).

FIG. 8 is a cross-sectional view taken along a line 8-8 in FIG. 7.

FIG. 9 is a cross-sectional view taken along a line 9-9 in FIG. 8.

### DESCRIPTION OF THE PREFERRED EMBODIMENT

Embodiments embodying the present invention will be described with reference to the drawings.

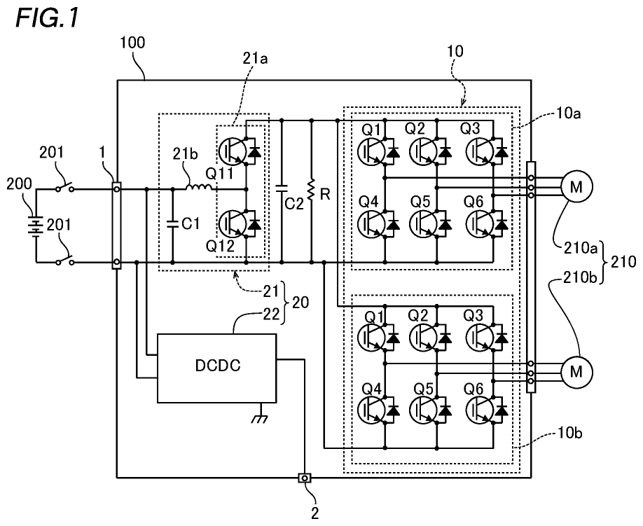

A configuration of a power conversion apparatus 100 according to one embodiment of the present invention will be described with reference to FIGS. 1 to 9. The power conversion apparatus 100, for example, is installed on a vehicle.

### (Entire Configuration of Power Conversion Apparatus)

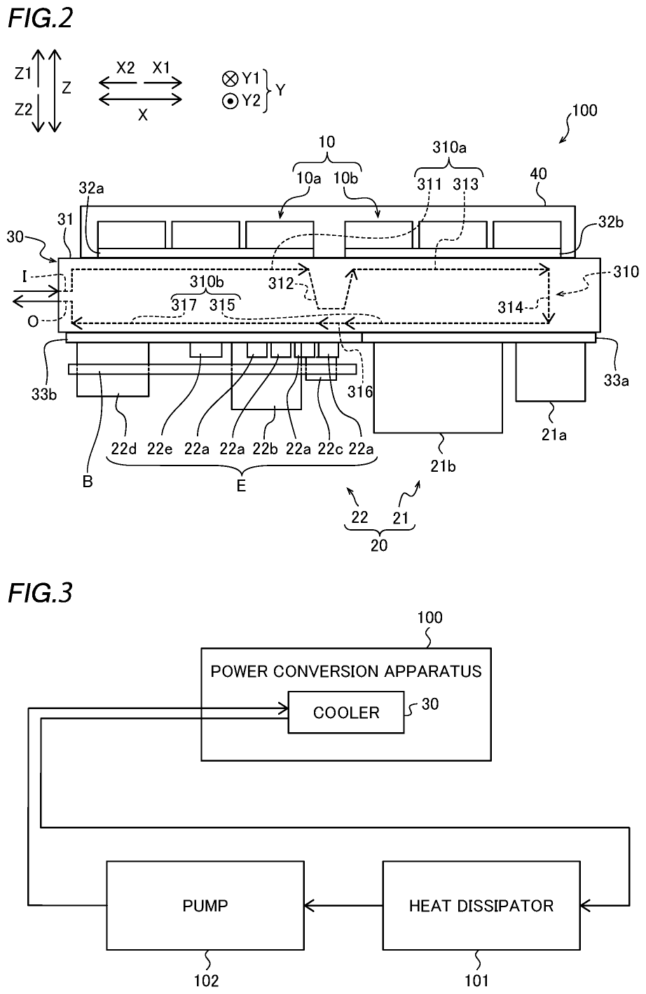

The entire configuration of the power conversion apparatus 100 according to one embodiment of the present invention is now described with reference to FIGS. 1 and 2.

A circuit configuration of the power conversion apparatus 100 is described with reference to FIG. 1. The power conversion apparatus 100 includes an inverter 10 and a converter 20.

The inverter 10 is configured to convert direct current power transformed by the converter 20 into alternate current power, and to supply the converted alternate current power to a load 210. The load 210, for example, is an electric motor. Switches 201 are connected between the power conversion apparatus 100 and the direct current power source 200.

The inverter 10 includes a first switching element module 10a and a second switching element module 10b configured to convert the direct current power into the alternate current power. The first switching element module 10a is used as an inverter for driving the vehicle. The second switching element module 10b is used as an inverter for generating electric power. Each of the first switching element module 10a and the second switching element module 10b includes semiconductor switching elements Q1, Q2, and Q3 that construct an upper arm, and semiconductor switching elements Q4, Q5, and Q6 that construct a lower arm.

The load 210 includes a first load 210a and a second load 210b. The first switching element module 10a is configured to convert the direct current power input from the direct current power source 200 into alternate current power, and to supply the alternate current power to the first load 210a. The second switching element module 10b s configured to convert the direct current power input from the direct current power source 200 into alternate current power, and to supply the alternate current power to the second load 210b.

The converter 20 is configured to transform direct current power input from the direct current power source 200. The converter 20 includes a boost converter 21, and a DC/DC converter 22. The DC/DC converter 22 is an example of the “direct current/direct current converter” in the claims.

The boost converter 21 is arranged on an input side of the inverter 10. The boost converter 21 is configured to increase a voltage of the direct current power input from the direct current power source 200, and to supply the direct current power whose voltage is increased to the inverter 10. The boost converter 21 includes a boost switching element module 21a, and a reactor 21b. The boost switching element module 21a includes boost switching elements Q11 and Q12. The boost switching elements Q11 and Q12 construct the upper and lower arms, respectively. In addition, the boost converter 21 includes a capacitor C1. The reactor 21b is connected between a positive side of the direct current power source 200, and a connection point between the boost switching element Q11 and the boost switching element Q12. The capacitor C1 is connected in parallel to the boost switching element Q12.

At least one of semiconductor switching elements Q1, Q2, Q3, Q4, Q5 and Q6 and the boost switching elements Q11 and Q12 can be a wide band-gap semiconductor element. The wide band-gap semiconductor element is a semiconductor element having a larger band gap than a silicon semiconductor element, and the wide band-gap semiconductor element can include SiC, GaN, diamond, gallium nitride group material, gallium oxide group material, AlN, AlGaN, ZnO, etc. A switching speed can be improved by using the wide band-gap semiconductor element for any of the semiconductor switching elements Q1 to Q6 and the boost switching elements Q11 and Q12 as compared with a case in which silicon semiconductor elements are used for all of them.

In addition, the power conversion apparatus 100 includes a capacitor C2 and a resistor R. The capacitor C2 and the resistor R are connected between the boost converter 21 and the inverter 10. The capacitor C2 and the resistor R are connected in parallel to each other.

The DC/DC converter 22 is configured to convert a voltage of the direct current power into a different voltage. Specifically, the DC/DC converter 22 is configured to step down the voltage of the direct current power input from the direct current power source 200 through a connector 1. Also, the DC/DC converter 22 supplies the step-down voltage to an output terminal 2.

A structure of the power conversion apparatus 100 is now described.

As shown in FIG. 2, the power conversion apparatus 100 includes a cooler 30 arranged between the inverter 10 and the converter 20. That is, the cooler 30 is interposed between a set of the first switching element module 10a and the second switching element module 10b, which construct the inverter 10, and a set of the boost converter 21 and the DC/DC converter 22. The cooler 30 has a flat plate shape.

In this specification, a facing direction in which the inverter 10 and the cooler 30 face each other is defined as a Z direction. One side and another side in the Z direction are defined as Z1 and Z2 directions, respectively. The cooler 30 has a rectangular shape as viewed from the Z1- or Z2-direction side. Also, a longitudinal direction of the cooler 30 as viewed from the Z1- or Z2-direction side is defined as an X direction. One side and another side in the X direction are defined X1 and X2 directions, respectively. Also, a direction (a shorter direction of the cooler 30) orthogonal to both the X and Z directions is defined as a Y direction. One side and another side in the Y direction are defined as Y1 and Y2 directions, respectively. The X direction and the Z direction are an example of a “longitudinal direction” and an example of a “facing direction”, respectively, in the claims.

The first switching element module 10a and the second switching element module 10b are arranged on the Z1-direction side of the flat-plate-shaped cooler 30. The first switching element module 10a and the second switching element module 10b are arranged adjacent to each other in the longitudinal direction (X direction) of the cooler 30. Also, a capacitor module 40 including the capacitor C2 is arranged on the Z1-direction side of the cooler 30 in the Y1-direction side part of the inverter 10.

In addition, the boost converter 21 and the DC/DC converter 22 are arranged on the Z2-direction side of the flat-plate-shaped cooler 30. The boost converter 21 is arranged adjacent to the DC/DC converter 22 in the X direction. The boost converter 21 is arranged on the X2-direction side of the DC/DC converter 22.

The DC/DC converter 22 includes direct current/direct current converter elements E and a converter circuit board B. The direct current/direct current converter elements E includes a converter switching element 22a, a transformer 22b, a resonant reactor 22c, a smoothing reactor 22d, and a diode element 22e. The power conversion apparatus 100 is configured to convert the voltage of the direct current power input from the direct current power source 200 into a different voltage by using the direct current/direct current converter elements E included in the DC/DC converter 22. The direct current/direct current converter elements E are mounted on the converter circuit board B. The converter circuit board B has a flat plate shape. The converter circuit board B is a printed circuit board (PCB) to which the direct current/direct current converter elements E are mounted. The converter circuit board B faces the cooler 30.

### (Configuration Relating to Cooling Flow Path)

The cooler 30 has a cooling flow path 310 formed inside the cooler. In this embodiment, the cooling flow path 310 includes a first inverter flow path 311, a connection flow path 312, a second inverter flow path 313, a connection flow path 314, a first converter flow path 315, a connection flow path 316, and a second converter flow path 317. The connection flow path 312 is an example of a “second connection flow path” in the claims. Also, the connection flow path 314 is an example of a “first connection flow path” in the claims.

The first inverter flow path 311 and the second inverter flow path 313 are formed inside the cooler 30 as an inverter-side flow path 310a arranged corresponding to the inverter 10. The first converter flow path 315 and the second converter flow path 317 are formed inside the cooler 30 as a converter-side flow path 310b arranged corresponding to the converter 20.

The inverter-side flow path 310a is arranged in an inverter 10 side (Z1-direction side) part of the cooler 30. The first inverter flow path 311 is a flow path arranged in the Z1-direction side part of the cooler 30 corresponding to the first switching element module 10a. The second inverter flow path 313 is a flow path arranged in the Z1-direction side part of the cooler 30 corresponding to the second switching element module 10b. The second inverter flow path 313 is formed downstream of the first inverter flow path 311. The first inverter flow path 311 is connected to the second inverter flow path 313 through the connection flow path 312.

The inverter 10, which is arranged on the Z1-direction side part of the cooler 30, is cooled by cooling liquid flowing through the inverter-side flow path 310a. Specifically, the first switching element module 10a, which constructs the inverter 10, is cooled by the cooling liquid flowing through the first inverter flow path 311. Also, the second switching element module 10b, which constructs the inverter 10, is cooled by the cooling liquid flowing through the second inverter flow path 313.

The converter-side flow path 310b is arranged in a converter 20 side (Z2-direction side) part of the of the cooler 30. The first converter flow path 315 is a flow path arranged in the Z2-direction side part of the cooler 30 corresponding to the boost converter 21. The second converter flow path 317 is a flow path arranged in the Z2-direction side part of the cooler 30 corresponding to the DC/DC converter 22. The second converter flow path 317 is formed downstream of the first converter flow path 315. The first converter flow path 315 is connected to the second converter flow path 317 through the connection flow path 316.

The converter 20 (boost converter 21 and DC/DC converter 22), which is arranged on the Z2-direction side part of the cooler 30, is cooled by the cooling liquid flowing through the converter-side flow path 310b. Specifically, the boost switching element module 21a and the reactor 21b, which construct the boost converter 21, are cooled by the cooling liquid flowing through the first converter flow path 315. Also, the direct current/direct current converter element E, which constructs the DC/DC converter 22, is cooled by the cooling liquid flowing through the second converter flow path 317. That is, the converter switching element 22a, the transformer 22b, the resonant reactor 22c, the diode element 22e, and the smoothing reactor 22d are cooled by the cooling liquid flowing through the second converter flow path 317.

The converter-side flow path 310b is connected to the inverter-side flow path 310a so that cooling liquid passes through the entire inverter-side flow path 310a and then passes through the converter-side flow path 310b in the cooling flow path 310. Accordingly, the first switching element module 10a and the second switching element module 10b are cooled by the cooling liquid flowing through the inverter-side flow path 310a, and the boost switching element module 21a, the reactor 21b and the direct current/direct current converter element E are then cooled by the cooling liquid flowing through the converter-side flow path 310b.

In this embodiment, the inverter-side flow path 310a and the converter-side flow path 310b are connected by a single flow path as the connection flow path 314 in the cooler 30. The connection flow path 314 is formed in one end (X1-direction side) part of the cooler 30 in the X direction in which the cooler extends.

The cooler 30 has a flow inlet I through which the cooling liquid flows into the cooler, and a flow outlet O through which the cooling liquid flows out of the cooler. The flow inlet I and the flow outlet O are arranged in another end (X2-direction side) part of the cooler 30 in the X direction.

The flow inlet I, the inverter-side flow path 310a, the connection flow path 314, the converter-side flow path 310b and flow outlet O are connected in this order in the cooling flow path 310. More specifically, the flow inlet I, the first inverter flow path 311, the connection flow path 312, the second inverter flow path 313, the connection flow path 314, the first converter flow path 315, the connection flow path 316, the second converter flow path 317, and the flow outlet O are connected in this order in the cooling flow path 310. The cooling flow path 310 turns in the connection flow path 314, which is arranged in one end (X1-direction side) part in the X direction.

The cooling liquid passes through the flow inlet I, which is arranged in the X2-direction side part of the cooler 30, into the first inverter flow path 311, flows through the connection flow path 312, the connection flow path 312, the second inverter flow path 313, the connection flow path 314, the first converter flow path 315, the connection flow path 316, and the second converter flow path 317 in this order, and then passes through the flow outlet O, which is arranged in the X2-direction side part of the cooler 30 out of the cooler. Because the power conversion apparatus 100 includes the inverter-side flow path 310a and the converter-side flow path 310b in the single cooler 30, the configuration of the apparatus can be compact as compared with a configuration in which the inverter 10 and the converter 20 are arranged on separate coolers configured to cool the inverter and the converter by using cooling flow paths formed in the separate coolers.

As shown in FIG. 3, the cooling liquid that flows out of the cooling flow path 310 of the cooler 30 is cooled by a heat dissipator 101, which is arranged outside the power conversion apparatus 100 to dissipate heat from the cooling liquid. The cooling liquid that is cooled by the heat dissipator 101 is fed by a pump 102, which is arranged outside the power conversion apparatus 100, and flows back into the cooling flow path 310 of the cooler 30. The heat dissipator 101 includes a heat exchanger to be cooled by outside air. The heat dissipator 101, for example, is a radiator. The pump 102 can be connected between the flow outlet O and the heat dissipator 101 so that the cooling liquid before the heat dissipation by the heat dissipator 101 is conveyed by the pump 102. Also, the cooling liquid is, for example, water, antifreeze, etc.

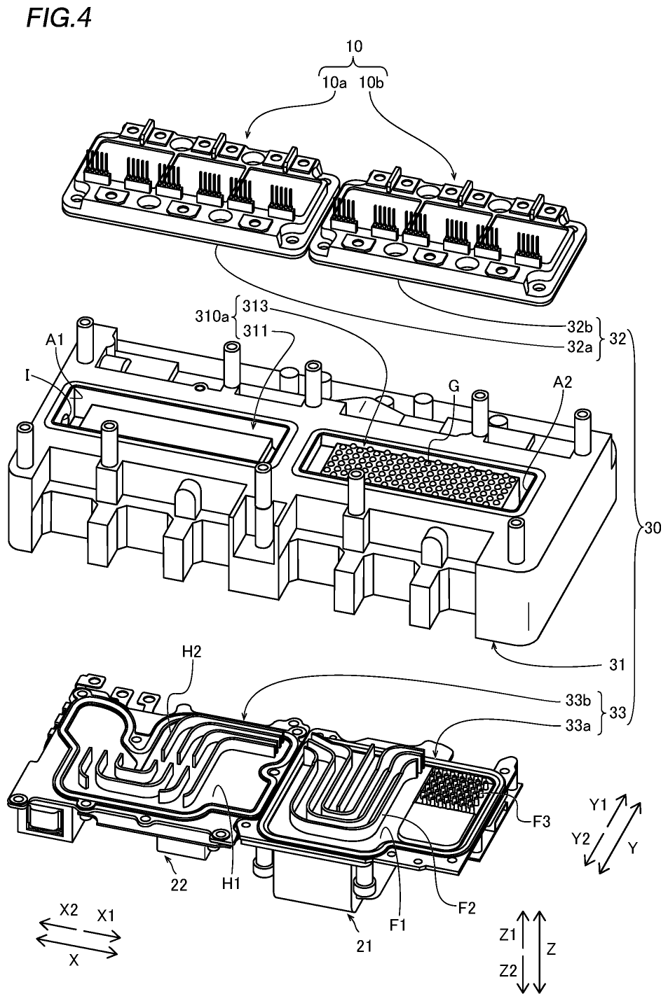

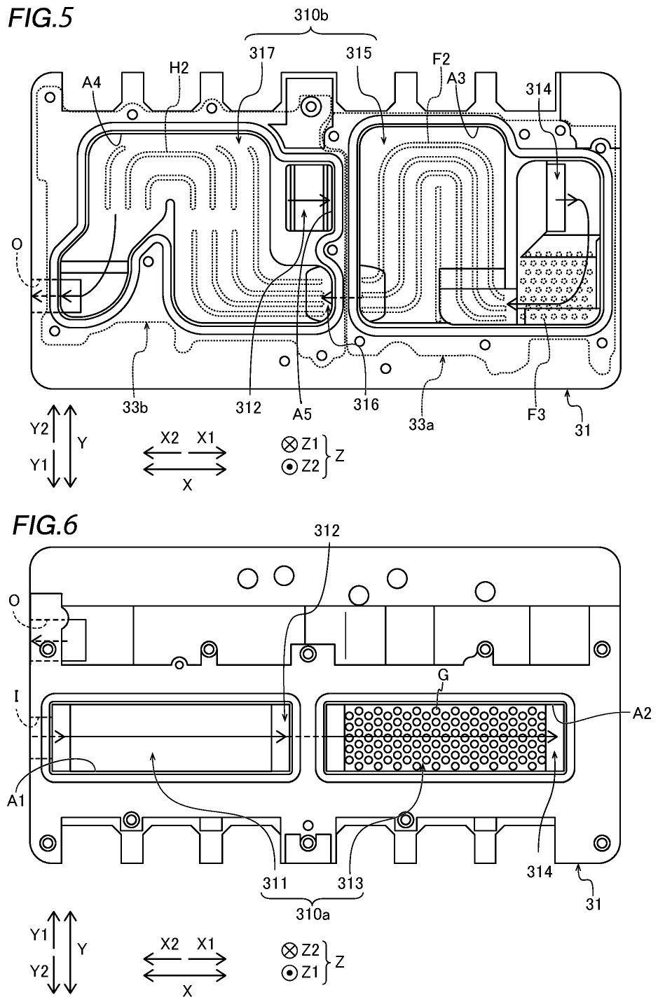

As shown in FIG. 4, the cooler 30 includes a base 31, a lid 32, and a lid 33. The inverter-side flow path 310a (see FIG. 4) and the converter-side flow path 310b (see FIG. 5) are formed in the base 31. The base 31 is an example of a “main body” in the claims. The lid 32 and the lid 33 are an example of an “inverter lid” and an example of a “converter lid”, respectively, in the claims. The base 31 may be formed integrally with a housing that houses the power conversion apparatus 100.

The lid 32 (see FIG. 4) is a flat-plate-shaped component to which the inverter 10 is attached. The lid 32 forms the inverter-side flow path 310a together with the base 31. The lid 32 includes a lid 32a and a lid 32b. The lid 32a corresponds to the first switching element module 10a. The lid 32b corresponds to the second switching element module 10b. The lid 32a and the lid 32b are an example of a “first inverter lid” and “an example of a second inverter lid”, respectively, in the claims.

The lid 32a is attached onto a base 31 side (Z2-direction side) of the first switching element module 10a. Also, the lid 32a is attached on the Z1-direction side of the base 31 to cover an opening A1 formed in the base 31. Accordingly, the lid 32a forms the first inverter flow path 311 of the inverter-side flow path 310a together with the base 31. The lid 32b is attached to the base 31 side (Z2-direction side) of the second switching element module 10b. Also, the lid 32b is attached on the Z1-direction side of the base 31 to cover an opening A2 formed in the base 31. Accordingly, the lid 32b forms the second inverter flow path 313 of the inverter-side flow path 310a together with the base 31. The first switching element module 10a and the second switching element module 10b are formed integrally with the lid 32a and the lid 32b, respectively. The first switching element module 10a and the second switching element module 10b may be formed separately from the lid 32a and the lid 32b, respectively.

The lid 33 is a flat-plate-shaped component attached to the converter 20. The lid 33 includes a lid 33a and a lid 33b. The lid 33a corresponds to the boost converter 21. The lid 33b corresponds to the DC/DC converter 22.

The lid 33a is attached onto the base 31 side (Z1-direction side) of the boost converter 21. The lid 33a includes a flat-plate-shaped base F1. In addition, the base F1 includes a plurality of walls F2 and a plurality of pillars F3. The plurality of walls F2 extends from the base F1 in the Z1 direction. The plurality of walls F2 is formed to meander as viewed from the Z1-direction side. The plurality of pillars F3 has a columnar shape, and protrudes from the base F1 in the Z1 direction. The base F1 may have fins instead of the pillars F3.

The lid 33b is attached onto the base 31 side (Z1-direction side) of the DC/DC converter 22. The lid 33b includes a flat-plate-shaped base H1. In addition, the base H1 includes a plurality of walls H2 and pillars F3. The plurality of walls H2 extends from the base H1 in the Z1 direction. The plurality of walls H2 is formed to meander as viewed from the Z1-direction side.

The base 31, the lids 32a, 32b, 33a and 33b are metal components. The base 31, the lids 32a, 32b, 33a and 33b are formed of a metal having a relatively high thermal conductivity, for example, aluminum. The lids 32a, 32b, 33a and 33b are attached to the base 31 by screws (not shown).

The lid 33 forms the converter-side flow path 310b (see FIG. 5) together with the base 31. The lid 33a is attached on the Z2-direction side of the base 31 to cover an opening A3 formed in the base 31. Accordingly, the lid 33a forms the first converter flow path 315 of the converter-side flow path 310b together with the base 31. The lid 33b is attached on the Z2-direction side of the base 31 to cover an opening A4 formed in the base 31. Accordingly, the lid 33b forms the second converter flow path 317 of the converter-side flow path 310b together with the base 31.

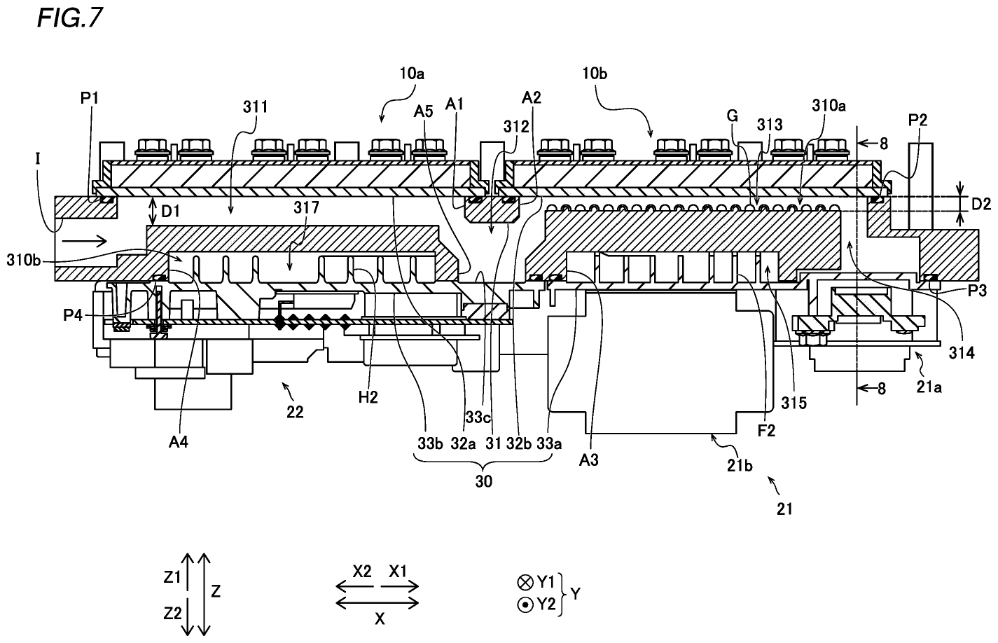

Also, the lid 33b is attached on the Z2-direction side of the base 31 to cover an opening A5 formed in the base 31. Accordingly, the lid 33b forms the connection flow path 312 together with the base 31. A part 33c (see FIG. 7) that covers the opening A5 of the lid 33b is an example of a “second-connection-flow-path former” in the claims. In this embodiment, the first converter flow path 315, the connection flow path 316, the second converter flow path 317, and the flow outlet O are arranged in this order from the X1-direction side. The connection flow path 312 is interposed between the first converter flow path 315 and the second converter flow path 317 as viewed from the Z2-direction side. The opening A5 may be covered by the lid 33a. In this case, the lid 33a forms a connection flow path 312 together with the base 31. In addition, the lid 33b or 33a can have a convex part inserted into the opening A5. According to this convex part, because a depth of the connection flow path 12 in the Z direction is reduced, it is possible to reduce a pressure drop of refrigerant. The convex part inserted into the opening A5 is an example of the “second-connection-flow-path former” in the claims.

The converter-side flow path 310b is formed so that flows of the cooling liquid meander as viewed from the Z2-direction side. The cooling flow path 310 is formed so that the cooling liquid branches into a plurality of flow paths in the converter-side flow path 310b.

The plurality of walls F2 protrudes toward an interior of the converter-side flow path 310b to produce the flows of the cooling liquid that meander. The cooling liquid that flows from the connection flow path 314 into the first converter flow path 315 is branched into a plurality of flow paths and meandered in a U-shape by the plurality of walls F2. The plurality of flow paths into which the cooling liquid that is branched by the plurality of walls F2 merges in the connection flow path 316.

The plurality of walls H2 protrudes toward an interior of the converter-side flow path 310b to produce the flows of the cooling liquid that meander. The cooling liquid that flows from the connection flow path 316 into the second converter flow path 317 is branched into a plurality of flow paths and meandered in a U-shape by the plurality of walls H2. The plurality of flow paths into which the cooling liquid that is branched by the plurality of walls H2 merges in a part immediately upstream of the flow outlet O.

As shown in FIG. 6, the inverter-side flow path 310a is formed linearly in the X direction (longitudinal direction) as viewed from the Z1-direction side. As discussed above, the linear inverter-side flow path 310a is formed by the base 31 and the lid 32.

The first inverter flow path 311 and the second inverter flow path 313 are arranged linearly in the X direction (longitudinal direction) and are connected to each other. Specifically, the first inverter flow path 311 and the second inverter flow path 313 are connected to each other through the connection flow path 312. In this embodiment, the flow inlet I, the first inverter flow path 311, the connection flow path 312, the second inverter flow path 313 and the connection flow path 314 are arranged in this order from the X2-direction side. The flow inlet I is arranged on the Y2-direction side relative to the flow outlet O.

A plurality of protrusions G is arranged in the inverter-side flow path 310a to adjust the flow of the cooling liquid. The plurality of protrusions G is arranged in the second inverter flow path 313, which is connected downstream of the first inverter flow path 311. As shown in FIG. 7, the plurality of protrusions G protrudes toward an interior of the inverter-side flow path 310a (second inverter flow path 313). The plurality of protrusions G has a hemispherical shape (dome shape). In the cooler 30 according to this embodiment, the plurality of protrusions G increases a flow speed of the cooling liquid that flows through the second inverter flow path 313, and bring the cooling liquid that flows through the second inverter flow path 313 into turbulence. As a result, the second switching element module 10b can be efficiently cooled by the cooling liquid that flows through the second inverter flow path 313. Although the plurality of protrusions G is provided in the inverter-side flow path 310a (second inverter flow path 313) corresponding to the second switching element module 10b in this embodiment, protrusions may be provided in the inverter-side flow path 310a (first inverter flow path 311) corresponding to the first switching element module 10a. Alternatively, protrusions may be provided in the inverter-side flow path 310a corresponding to both the first switching element module 10a and the second switching element module 10b. In this embodiment, it is assumed that heat generated by the second switching element module 10b is greater than heat generated by the first switching element module 10a. Although the lid 32a and the lid 32b in this embodiment do not include fins, at least one of the lid 32a and the lid 32b may include fins to improve cooling performance.

As shown in FIG. 7, the cooling flow path 310 is formed so that the inverter-side flow path 310a and the converter-side flow path 310b overlap each other as viewed from the Z1-direction side or the Z2-direction side.

The connection flow path 312, which connects the first inverter flow path 311 to the second inverter flow path 313, has a curved U-shape in the Z2-direction side part on which the converter 20 is arranged. The connection flow path 312 is formed by the base 31 and the lid 33b, as discussed above.

In this embodiment, a flow depth of the second inverter flow path 313 is smaller than a flow depth of the first inverter flow path 311. Specifically, as shown in FIG. 7, the second inverter flow path 313 is formed so that a flow path depth D2 in the Z direction of the second inverter flow path 313 is smaller (shallower) than a flow path depth D1 in the Z direction of the first inverter flow path 311.

The connection flow path 314 extends in the Z direction to connect the second inverter flow path 313 on the Z1-direction side to the first converter flow path 315 on the Z2-direction side.

In addition, enclosing gaskets P1, P2, P3 and P4 are fitted into the base 31 to prevent leakage of the cooling liquid. The gaskets P1, P2, P3 and P4 are pressed against the base 31 by the lids 32a, 32b, 33a and 33b, respectively.

The reactor 21b is attached to the Z2-direction side part of the lid 33a. Thermally conductive grease (heat-dissipating grease) is applied to a part between the lid 33a and the reactor 21b.

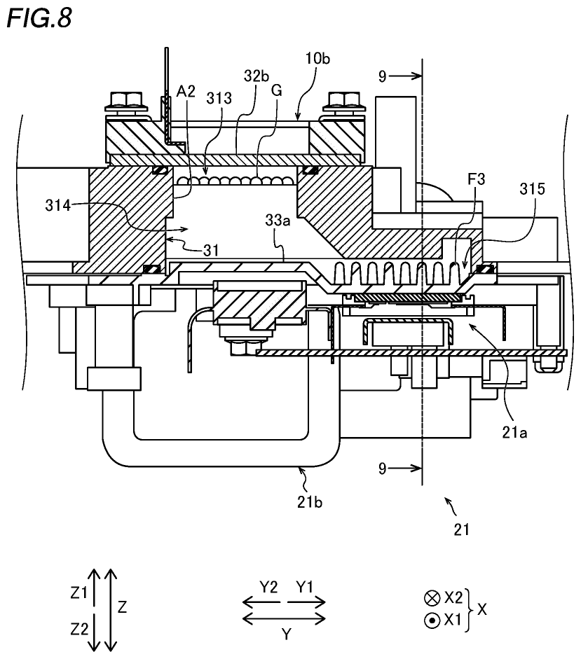

As shown in FIG. 8, the connection flow path 314 is formed by the base 31, the lid 32b and the lid 33a. The pillars F3 of the lid 33a are arranged on the Y1-direction side with respect to the protrusions G of the base 31. The pillars F3 of the lid 33a are arranged to overlap the boost switching element module 21a as viewed from the Z1-direction side or the Z2-direction side. In this embodiment, because a heat dissipation area (heat transfer area) in the first converter flow path 315 is increased by the plurality of pillars F3, it is possible to more efficiently cool the boost switching element module 21a. The boost switching element module 21a is attached to the Z2-direction side part of the lid 33a. Thermally conductive grease (heat-dissipating grease) is applied to a part between the lid 33a and the boost switching element module 21a. The boost switching element module 21a is arranged on the Y1-direction side of the reactor 21b. The boost switching element modules 21a and the reactor 21b may be directly mounted onto the lid 33a.

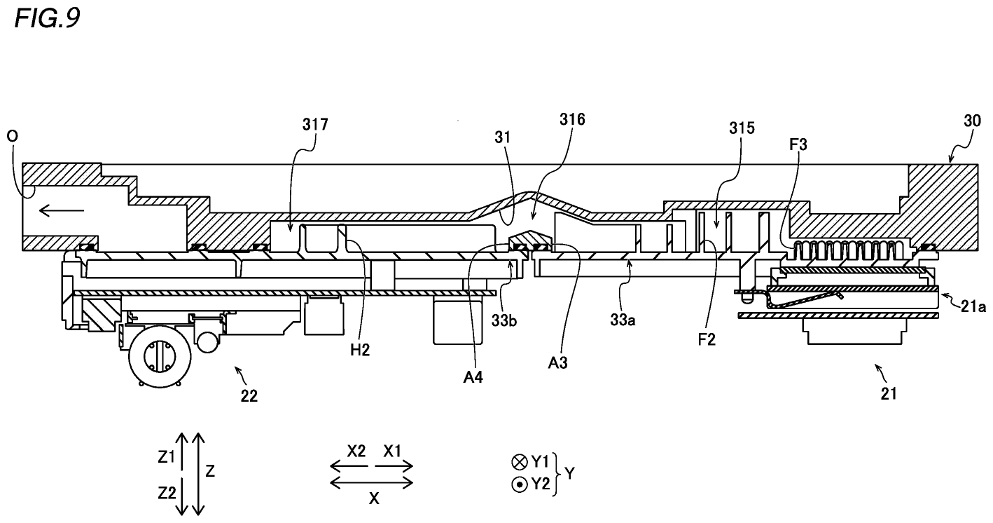

As shown in FIG. 9, the connection flow path 316 is formed between the first converter flow path 315 and the second converter flow path 317 in the X direction. The connection flow path 316 has a U-shaped shape that is curved toward the Z1-direction side where the converter 20 is arranged. The connection flow path 316 is formed to straddle a part between the lid 33a and the lid 33B in the X direction.

### Advantages of the Embodiment

In this embodiment, the following advantages are obtained.

In this embodiment, the cooler 30 arranged between the inverter 10 and the converter 20 has a cooling flow path 310 including an inverter-side flow path 310a, and a converter-side flow path 310b connected to the inverter-side flow path 310a. Accordingly, the inverter 10 and the converter 20 can be individually cooled by flowing the cooling liquid through the inverter-side flow path 310a and then the converter-side flow path 310b. According to this configuration, because temperature difference in the cooling liquid flowing through the same flow path can be reduced, it is possible to prevent unintended convection of the cooling liquid caused by temperature difference. Consequently, the inverter 10 and the converter 20 can be efficiently cooled by the cooling liquid flowing through the cooling flow path 310. Also, because the converter-side flow path 310b is connected to the inverter-side flow path 310a so that cooling liquid passes through the entire inverter-side flow path 310a and then passes through the converter-side flow path 310b in the cooling flow path 310, the inverter 10 can be efficiently cooled as compared with a case in which cooling liquid passes through the converter-side flow path 310b and then passes through the inverter-side flow path 310a.

In this embodiment, as described above, the cooling flow path 310 includes a connection flow path 314 arranged in one end (X1-direction side) part in a longitudinal direction in which the cooler 30 extends to connect the converter-side flow path 310b to the inverter-side flow path 310a in the cooler 30. According to this configuration, because the converter-side flow path 310b is connected to the inverter-side flow path 310a in the cooler 30 by the connection flow path 314, the cooling flow path 310 can be formed to flow the cooling liquid through the inverter-side flow path, the first connection flow path and then through the converter-side flow path. Consequently, a configuration of the cooler 30 can be simplified dissimilar to a case in which the converter-side flow path 310b is connected to the inverter-side flow path 310a by a flow path outside the cooler 30. Also, in a case in which the connection flow path 314 is a single flow path, because the converter-side flow path 310b is connected to the inverter-side flow path 310a by the connection flow path 314, the configuration of the cooler 30 can be further simplified as compared with a case in which the converter-side flow path 310b is connected to the inverter-side flow path 310a by two or more flow paths.

In this embodiment, as described above, the cooler 30 has a flow inlet I through which the cooling liquid flows into the cooler, and a flow outlet O through which the cooling liquid flows out of the cooler. In addition, the flow inlet I, the inverter-side flow path 310a, the connection flow path 314, the converter-side flow path 310b, and the flow outlet O are connected in this order, and the cooling flow path 310 turns in the connection flow path 314, which is arranged in the one end (X1-direction side) part in the longitudinal direction. According to this configuration, it is possible to prevent size increase of the cooler 30 in the X direction (longitudinal direction) as compared with a case in which the flow inlet I, the inverter-side flow path 310a, the connection flow path 314, the converter-side flow path 310b and the flow outlet O are connected linearly in the X direction (longitudinal direction). Also, the configuration of the cooler 30 can further be simplified as compared with a case in which the inverter-side flow path 310a and the converter-side flow path 310b are alternately connected to each other.

In this embodiment, as described above, the cooling flow path 310 is formed so that the inverter-side flow path 310a and the converter-side flow path 310b overlap each other as viewed from the Z1-direction side or the Z2-direction side. According to this configuration, it is possible to prevent size increase of the cooler 30 in the X direction or the Y-direction as compared with a case in which the cooling flow path 310 is not formed so that the inverter-side flow path 310a and the converter-side flow path 310b overlap each other as viewed from the Z1-direction side or the Z2-direction side.

In this embodiment, as described above, the inverter-side flow path 310a is formed linearly in the X direction (the longitudinal direction of the cooler 30) as viewed from the Z1-direction side; and the converter-side flow path 310b is formed so that flows of the cooling liquid meander as viewed from the Z2-direction side. According to this configuration, because the inverter-side flow path 310a is formed linearly in the X direction (the longitudinal direction of the cooler 30), the inverter-side flow path 310a can be prevented from becoming complicated so that the configuration of the cooler 30 can be simplified. Also, because the converter-side flow path 310b is formed so that flows of the cooling liquid meander, the converter 20 can be more efficiently cooled by meandering the flows of the cooling liquid in the converter-side flow path 310b depending on an arrangement area of the converter 20.

In this embodiment, as described above, the cooling flow path 310 is formed so that the cooling liquid branches into a plurality of flow paths in the converter-side flow path 310b. Accordingly, it is possible to separately flow the cooling liquid through the converter-side flow path 310b in a wide area. As a result, the cooling liquid can be distributed evenly in the converter-side flow path 310b so that the converter 20 can be more efficiently cooled.

Also, in this embodiment, as described above, the flow inlet I and the flow outlet O are arranged in another end (X2-direction side) part of the cooler 30 in the longitudinal direction. According to this configuration, because both pipes that are connected to the power conversion apparatus 100 to flow the cooling fluid into and out of power conversion apparatus are connected to the X2-direction side part (another end part in the longitudinal direction) of the cooler 30, it is possible to prevent size increase of the power conversion apparatus 100 including the pipes in the X direction (longitudinal direction) of the cooler as compared with a case in which the pipes are connected to the X1-direction side part (one end part in the longitudinal direction) and the X2-direction side part of the cooler 30.

In this embodiment, as described above, the cooler 30 includes a base 31 including the inverter-side flow path 310a and the converter-side flow path 310b formed in the base, and a flat-plate-shaped lid 32 to which the inverter 10 is attached, and which forms the inverter-side flow path 310a formed linearly as viewed from the Z1-direction side together with the base 31. According to this configuration, because the lid 32 to which the inverter 10 is attached can be brought in direct contact with the cooling liquid flowing through the inverter-side flow path 310a, it is possible to efficiently dissipate heat generated by the inverter 10 through the lid 32.

In this embodiment, as described above, the plurality of protrusions G is arranged in the inverter-side flow path 310a, and protrudes toward an interior of the inverter-side flow path 310a to adjust a flow of the cooling liquid. According to this configuration, a flow speed of the cooling liquid flowing in the inverter-side flow path 310a can be increased by adjusting the flow of the cooling liquid by using the plurality of protrusions G protruding toward the interior of the inverter-side flow path 310a (cooling flow path 310). As a result, it is possible to efficiently cool the inverter 10. Also, because a heat dissipation area (heat transfer area) in the inverter-side flow path 310a can be increased by the plurality of protrusions G, it is possible to more efficiently cool the inverter 10.

In this embodiment, as described above, the inverter 10 includes a first switching element module 10a and a second switching element module 10b configured to convert the direct current power into the alternate current power. In addition, the inverter-side flow path 310a includes a first inverter flow path 311 formed corresponding to the first switching element module 10a and a second inverter flow path 313 formed corresponding to the second switching element module 10b. In addition, the first inverter flow path 311 and the second inverter flow path 313 are arranged linearly in the X direction (longitudinal direction) and are connected to each other. According to this configuration, the first switching element module 10a and the second switching element module 10b can be cooled by the cooling liquid flowing through the first inverter flow path 311 and the cooling liquid flowing through the second inverter flow path 313, respectively. Consequently, it is possible to more efficiently cool the first switching element module 10a and the second switching element module 10b as compared with a case in which the first switching element module 10a and the second switching element module 10b are cooled by the cooling liquid flowing through the same flow path.

In this embodiment, as described above, the cooling flow path 310 includes the connection flow path 312 having a U shape curved toward a side (the Z2-direction side) where the converter 20 is arranged, and connecting the first inverter flow path 311 and the second inverter flow path 313 to each other. According to this configuration, the first inverter flow path 311 and the second inverter flow path 313 can be connected by the U-shaped connection flow path 312, which is curved toward the side where the converter 20 is arranged to be able to bypass a part between the first and second inverter flow paths. As a result, the first inverter flow path 311 and the second inverter flow path 313 can be more flexibly connected depending on arrangements and shapes of the first inverter flow path 311 and the second inverter flow path 313 as compared with a case in which the first inverter flow path 311 and the second inverter flow path 313 are connected by a linear flow path.

In this embodiment, as described above, the second inverter flow path 313 is formed downstream of the first inverter flow path 311, and the plurality of protrusions G is arranged in the second inverter flow path 313, and protrudes toward an interior of the second inverter flow path 313 to adjust a flow of the cooling liquid. According to this configuration, a flow speed of the cooling liquid flowing through the second inverter flow path 313 can be increased by adjusting the flow of the cooling liquid flowing through the second inverter flow path 313 by using the plurality of protrusions G protruding toward the interior of the second inverter flow path 313. As a result, it is possible to efficiently cool the second switching element module 10b. In addition, as compared with a case in which both the first inverter flow path 311 and the second inverter flow path 313 include such a plurality of protrusions G, it is possible to prevent a structure of the inverter-side flow path 310a in the cooler 30 from becoming complicated and weight increase of the cooler 30 caused by increase of the plurality of protrusions G. Also, because a heat dissipation area (heat transfer area) in the second inverter flow path 313 can be increased by the plurality of protrusions G, it is possible to more efficiently cool the second switching element module 10b.

In this embodiment, as described above, the second inverter flow path 313 is formed downstream of the first inverter flow path 311; and a flow depth D2 of the second inverter flow path 313 is smaller than a flow depth of the first inverter flow path 311. According to this configuration, because a cross-sectional area of the second inverter flow path 313 can be smaller than a cross-sectional area of the first inverter flow path 311, a flow speed of the cooling liquid flowing through the second inverter flow path 313 can be greater than a flow speed of the cooling liquid flowing through the first inverter flow path 311. As a result, the second switching element module 10b can be more efficiently cooled by the second inverter flow path 313 as compared with a case in which the first switching element module 10a is cooled by the first inverter flow path 311. Consequently, it is possible to sufficiently cool the second switching element module 10b even in a case in which the second switching element module 10b generates a larger amount of heat than the first switching element module 10a.

In this embodiment, as described above, the cooler 30 includes a lid 33 forming the converter-side flow path 310b, which is formed so that flows of the cooling liquid meander as viewed from the Z2-direction side, together with the base 31. In addition, the converter 20 is attached to the lid 33. In addition, the lid 33 includes a plurality of walls F2 and H2 protruding toward an interior of the converter-side flow path 310b to produce the flows of the cooling liquid that meander. According to this configuration, because flows of the cooling liquid that flow through the converter-side flow path 310b are meandered by the plurality of walls F2 and H2, the converter 20 can be more efficiently cooled by meandering the cooling liquid flowing through the converter-side flow path 310b depending on an arrangement area of the converter 20.

In this embodiment, as described above, the converter 20 includes a DC/DC converter 22 configured to convert a voltage of the direct current power into a different voltage, and a boost converter 21 configured to boost the direct current power input from the direct current power source 200 and to supply the boosted direct current power to the inverter 10. The converter-side flow path 310b includes a first converter flow path 315 formed corresponding to the boost converter 21, and a second converter flow path 317 formed corresponding to the DC/DC converter 22. According to this configuration, since the boost converter 21 and the DC/DC converter 22 can be individually cooled by the cooling liquid through the first converter flow path 315 and the second converter flow path 317, respectively, the boost converter 21 and the DC/DC converter 22 can be more efficiently cooled.

### Modified Embodiments

Note that the embodiments disclosed this time must be considered as illustrative in all points and not restrictive. The scope of the present invention is not shown by the above description of the embodiments but by the scope of claims for patent, and all modifications (modified embodiments) within the meaning and scope equivalent to the scope of claims for patent are further included.

For example, while the example in which the converter-side flow path 310b is connected to the inverter-side flow path 310a by a single flow path as the connection flow path 314 (first connection flow path) has been shown in the aforementioned embodiment, the present invention is not limited to this. For example, the converter-side flow path may be connected to the inverter-side flow path by a plurality of first connection flow paths.

While the example in which the cooling flow path 310 turns in the connection flow path 314 (first connection flow path), which is arranged in one end (X1-direction side) part in the X direction (the longitudinal direction of the cooler 30) has been shown in the aforementioned embodiment, the present invention is not limited to this. In the present invention, the cooling flow path may be turned by a pipe outside the cooler. Alternatively, the cooling flow path may turn in a central part in the longitudinal direction of the cooler.

While the example in which the cooling flow path 310 is formed so that the inverter-side flow path 310a and the converter-side flow path 310b overlap each other as viewed from the Z1-direction side or the Z2-direction side (in the facing direction) has been shown in the aforementioned embodiment, the present invention is not limited to this. In the present invention, the cooling flow path may be formed so that the inverter-side flow path and the converter-side flow path do not overlap each other as viewed in the facing direction.

While the example in which the inverter-side flow path 310a is formed linearly in the X direction as viewed from the Z1-direction side (in the facing direction) has been shown in the aforementioned embodiment, the present invention is not limited to this. In the present invention, the inverter-side flow path may be formed to meander as viewed in the facing direction in which the inverter and the cooler face each other.

While the example in which the converter-side flow path 310b is formed so that flows of the cooling liquid meander as viewed from the Z2-direction side (in the facing direction) has been shown in the aforementioned embodiment, the present invention is not limited to this. In the present invention, the converter-side flow path 310b may be formed so that the cooling liquid linearly flows.

While the example in which the cooling flow path 310 is formed so that the cooling liquid branches into a plurality of flow paths in the converter-side flow path 310b has been shown in the aforementioned embodiment, the present invention is not limited to this. In the present invention, the converter-side flow path may be a single flow path.

While the example in which the flow inlet I and the flow outlet O are arranged in another end (X2-direction side) part in the X direction (the longitudinal direction of the cooler 30) has been shown in the aforementioned embodiment, the present invention is not limited to this. In the present invention, at least one of the flow inlet and the flow outlet may be arranged in one end part in the longitudinal direction of the cooler. Alternatively, at least one of the flow inlet and the flow outlet may be arranged at one or another end part in the shorter direction of the cooler. For example, both the flow inlet and the flow outlet may be arranged at one or another end part in the shorter direction of the cooler.

While the example in which the cooler 30 includes the base 31 (main part), and the flat-plate-shaped lid 32 (inverter lid) which forms the inverter-side flow path 310a together with the base 31, has been shown in the aforementioned embodiment, the present invention is not limited to this. In the present invention, the inverter-side flow path in the cooler may be formed only by the main body.

While the example in which the plurality of protrusions G is arranged in the inverter-side flow path 310a, and protrudes toward an interior of the inverter-side flow path 310a to adjust a flow of the cooling liquid has been shown in the aforementioned embodiment, the present invention is not limited to this. In the present invention, the inverter-side flow path may be formed by flat inner walls without the plurality of protrusions.

While the example in which the inverter-side flow path 310a includes a first inverter flow path 311 formed corresponding to the first switching element module 10a and a second inverter flow path 313 formed corresponding to the second switching element module 10b has been shown in the aforementioned embodiment, the present t invention is not limited to this. In the present invention, a common flow path corresponding to the first switching element module and the second switching element module may be formed.

While the example in which the first inverter flow path 311 and the second inverter flow path 313 are arranged linearly in the X direction (longitudinal direction) and are connected to each other has been shown in the aforementioned embodiment, the present invention is not limited to this. In the present invention, the first inverter flow path and the second inverter flow path may be arranged adjacent to each other in the shorter direction of the cooler.

While the example in which the cooling flow path 310 includes the connection flow path 312 (second connection flow path) having a U shape curved toward a side (the Z2-direction side) where the converter 20 is arranged, and connecting the first inverter flow path 311 and the second inverter flow path 313 to each other has been shown in the aforementioned embodiment, the present invention is not limited to this. In the present invention, the second inverter flow path may be connected to the first inverter flow path by a linear second connection flow path.

While the example in which the plurality of protrusions G is arranged in the second inverter flow path 313, and protrudes toward an interior of the second inverter flow path 313 to adjust a flow of the cooling liquid has been shown in the aforementioned embodiment, the present invention is not limited to this. In the present invention, the plurality of protrusions may be arranged in both the first and second inverter flow paths.

While the example in which a flow depth D2 of the second inverter flow path 313 is smaller than a flow depth of the first inverter flow path 311 has been shown in the aforementioned embodiment, the present invention is not limited to this. In the present invention, the second inverter flow path may have a flow depth greater than a flow depth of the first inverter flow path. Alternatively, the second inverter flow path may have substantially the same flow path depth as the first inverter flow path.

While the example in which the cooler 30 includes a lid 33 forming the converter-side flow path 310b together with the base 31 (main body) has been shown in the aforementioned embodiment, the present invention is not limited to this. In the present invention, the converter-side flow path in the cooler may be formed only by the main body.

While the example in which the converter-side flow path 310b includes a first converter flow path 315 formed corresponding to the boost converter 21, and a second converter flow path 317 formed corresponding to the DC/DC converter 22 (direct current/direct current converter) has been shown in the aforementioned embodiment, the present invention is not limited to this. In the present invention, a common flow path corresponding to the boost converter and the direct current/direct current converter may be formed.

While the example in which the inverter 10 includes two switching element modules, which are the first switching element module 10a and the second switching element module 10b, has been shown in the aforementioned embodiment, the present invention is not limited to this. A power conversion apparatus according to present invention can include only one switching element module, which is provided in the inverter 10. In this power conversion apparatus, a single inverter-side flow path is provided, and a single lid that covers the inverter-side flow path is correspondingly provided. Also, the plurality of protrusions protruding toward an interior of the inverter-side flow path is provided in the single inverter-side flow path.

What is claimed is:

1. A power conversion apparatus comprising:
a converter configured to transform direct current power input from a direct current power source;
an inverter configured to convert the direct current power transformed by the converter into alternate current power and to supply the converted alternate current power to a load; and
a cooler arranged between the inverter and the converter, wherein
the cooler includes, inside thereof, a cooling flow path having an inverter-side flow path and a converter-side flow path connected to the inverter-side flow path;
a plurality of protrusions is formed in a part of the inverter-side flow path; and
the converter-side flow path is connected to the inverter-side flow path so that cooling liquid passes through the entire inverter-side flow path and then passes through the converter-side flow path in the cooling flow path.

2. The power conversion apparatus according to claim 1, wherein the cooling flow path further includes a first connection flow path arranged in one end part in a longitudinal direction in which the cooler extends, to connect the converter-side flow path to the inverter-side flow path in the cooler.

3. The power conversion apparatus according to claim 2, wherein
the cooler has a flow inlet through which the cooling liquid flows into the cooler, and a flow outlet through which the cooling liquid flows out of the cooler; and
the cooling flow path is arranged such that the flow inlet, the inverter-side flow path, the first connection flow path, the converter-side flow path, and the flow outlet are connected in this order, and turns in the first connection flow path, which is arranged in the one end part in the longitudinal direction.

4. The power conversion apparatus according to claim 3, wherein the cooling flow path is formed so that the inverter-side flow path and the converter-side flow path overlap each other as viewed in a facing direction in which the inverter and the cooler face each other.

5. The power conversion apparatus according to claim 3, wherein
the inverter-side flow path is formed linearly in the longitudinal direction as viewed in a facing direction in which the inverter and the cooler face each other; and
the converter-side flow path is formed so that a flow of the cooling liquid meanders as viewed in the facing direction.

6. The power conversion apparatus according to claim 5, wherein the cooling flow path is formed so that the cooling liquid branches into a plurality of flow paths in the converter-side flow path.

7. The power conversion apparatus according to claim 3, wherein the flow inlet and the flow outlet are arranged in another end part of the cooler in the longitudinal direction.

8. The power conversion apparatus according to claim 5, wherein the cooler includes a main body where the inverter-side flow path and the converter-side flow path are formed, and a flat-plate-shaped inverter lid to which the inverter is attached, and which forms the inverter-side flow path formed linearly as viewed in the facing direction together with the main body.

9. The power conversion apparatus according to claim 8, wherein the plurality of protrusions is arranged in the inverter-side flow path to protrude toward an interior of the inverter-side flow path.

10. The power conversion apparatus according to claim 3, wherein
the inverter includes a first switching element module and a second switching element module configured to convert the direct current power into the alternate current power; and
the inverter-side flow path includes a first inverter flow path formed corresponding to the first switching element module and a second inverter flow path formed corresponding to the second switching element module, and the first inverter flow path and the second inverter flow path arranged linearly in the longitudinal direction are connected to each other.

11. The power conversion apparatus according to claim 10, wherein the cooling flow path further includes a second connection flow path curved toward a side where the converter is arranged, and connecting the first inverter flow path and the second inverter flow path to each other.

12. The power conversion apparatus according to claim 10, wherein
the second inverter flow path is arranged downstream of the first inverter flow path; and
the plurality of protrusions is arranged in the second inverter flow path.

13. The power conversion apparatus according to claim 12, wherein the plurality of protrusions is arranged in the second inverter flow path to protrude toward an interior of the second inverter flow path and to adjust a flow of the cooling liquid.

14. The power conversion apparatus according to claim 10, wherein
the second inverter flow path is formed downstream of the first inverter flow path; and
the second inverter flow path has a flow depth shallower than a flow depth of the first inverter flow path.

15. The power conversion apparatus according to claim 8, wherein
the cooler further includes a converter lid forming the converter-side flow path, which meanders as viewed in the facing direction, together with the main body;
the converter is attached to the converter lid; and
the converter lid includes a plurality of walls protruding toward an interior of the converter-side flow path to meander the flows of the cooling liquid.

16. The power conversion apparatus according to claim 15, wherein
the converter includes a direct current/direct current converter configured to transform a voltage of the direct current power into a different voltage, and a boost converter configured to boost the direct current power input from the direct current power source and to supply the boosted direct current power to the inverter; and
the converter-side flow path includes a first converter flow path formed corresponding to the boost converter, and a second converter flow path formed corresponding to the direct current/direct current converter.

17. The power conversion apparatus according to claim 11, wherein
the cooler includes a main body where the inverter-side flow path and the converter-side flow path are formed, and a converter lid forming the converter-side flow path together with the main body;
the second connection flow path has an opening on a side where the converter is arranged; and
the converter lid includes a second-connection-flow-path forming portion covering the opening.

18. The power conversion apparatus according to claim 17, wherein the second-connection-flow-path forming portion includes a convex part protruding toward a side where the inverter is arranged.

19. The power conversion apparatus according to claim 3, wherein
the cooler includes a main body where the inverter-side flow path and the converter-side flow path are formed, and a flat-plate-shaped inverter lid to which the inverter is attached, and which forms the inverter-side flow path together with the main body; and
the plurality of protrusions is arranged in the body part to protrude toward an interior of the inverter-side flow path.

20. The power conversion apparatus according to claim 19, wherein the inverter lid includes a fin.

21. The power conversion apparatus according to claim 19, wherein
the inverter includes a first switching element module and a second switching element module configured to convert the direct current power into the alternate current power;
the inverter-side flow path includes a first inverter flow path formed corresponding to the first switching element module and a second inverter flow path formed corresponding to the second switching element module;
the cooler includes a main body where the inverter-side flow path and the converter-side flow path are formed, and flat-plate-shaped first and second inverter lids to which the first and second switching element modules are attached and which form the first and second inverter flow paths, respectively; and
the plurality of protrusions is arranged in at least one of the first and the second inverter flow paths.
